(19) United States
(12) Patent Application Publication
(10) Pub. No.: US 2025/0126772 A1
(43) Pub. Date: Apr. 17, 2025

(54) DOPING PROFILE FOR REDUCED FLOATING BODY EFFECT IN 4F2 DRAM

(71) Applicant: Applied Materials, Inc., Santa Clara, CA (US)

(72) Inventors: Milan PEŠIC, Paoli, PA (US); Bruno COPPOLELLI, Reggio Emilia (IT)

(73) Assignee: Applied Materials, Inc., Santa Clara, CA (US)

(21) Appl. No.: 18/899,949

(22) Filed: Sep. 27, 2024

Related U.S. Application Data
(60) Provisional application No. 63/589,920, filed on Oct. 12, 2023.

(51) Int. Cl. H10B 12/00

(52) U.S. Cl. CPC H10B 12/315; H10B 12/05

(57) ABSTRACT

The present technology includes vertical cell array transistor (VCAAT) with improved floating body effect. The arrays one or more bit lines arranged in a first horizontal direction and one or more word lines arranged in a second horizontal direction. The arrays include one or more channels extending in a vertical direction generally orthogonal to the first direction and the second horizontal direction, such that the bit lines intersect with a source/drain region of the plurality of channels, and the word lines intersect with gate regions of the plurality of channels. Arrays include where the source/drain region has a first section adjacent to a source/drain junction and a second section adjacent to a channel body, where the first section has a doping concentration that greater than a doping concentration of the second section.

### CROSS-REFERENCES TO RELATED APPLICATIONS

This application claims the benefit of priority to U.S. Patent Application No. 63/589,920 filed Oct. 12, 2023, the contents of which are hereby incorporated by reference in their entirety for all purposes.

### TECHNICAL FIELD

This disclosure generally describes designs for a 4F² dynamic random access memory array. More specifically, this disclosure describes a 4F² memory array with a decreased floating body effect and improved threshold voltage stability.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries.

Dynamic random-access memory (DRAM) architectures continue to scale down over time. For example, a one transistor, one capacitor (1T-1C) DRAM cell architecture has successfully scaled down from an 8F² size to a 6F² size (where F is the minimum feature size). Further design scheme changes from 6F² to 4F² may help further improve area density. In the 4F² DRAM scheme, a storage node (capacitor) and bit line are located at the top and bottom of a vertical cell transistor, leaving the channel completely isolated from the body. Due to this arrangement, the floating body effect, which is not an issue for current 8F² or 6F² DRAM cell architecture due to the body connection of the channels, becomes a major technical challenge for 4F² DRAM. Therefore, improvements in the art are needed.

### BRIEF SUMMARY

The present technology is generally directed to vertical cell array transistors (VCATs), as well as methods of forming such devices. Transistors include one or more bit lines arranged in a first horizontal direction, one or more word lines arranged in a second horizontal direction, and one or more channels extending in a vertical direction. Transistors include where the vertical direction is generally orthogonal to the first horizontal direction and the second horizontal direction such that the one or more bit lines intersect with a source/drain region of the one or more channels, and the one or more word lines intersect with a gate region of the one or more channels. Transistors include where the source/drain region contains a first section adjacent to a source/drain junction and a second section adjacent to a channel body, where the first section has a doping concentration that greater than a doping concentration of the second section.

In embodiments, a doping concentration of the source/drain region exhibits a Gaussian (normal) distribution having a peak concentration at approximately the source/drain junction. In more embodiments, the doping concentration of the first section is greater than or about 2 times higher than the doping concentration of the second section. Furthermore in embodiments, the doping concentration of the first section is greater than 1×10¹⁹ cm⁻³. In more embodiments, the doping concentration of the first section is greater than 4×10¹⁹ cm⁻³. Additionally or alternatively, in embodiments, the doping concentration of the second section is less than or about 1×10¹⁹ cm⁻³. In further embodiments, the channel further includes one or more p-doped regions. Embodiments include where the channel exhibits a height extending between the source/drain region and a second source/drain region, where the one or more p-doped regions is formed at a height of about 20% to about 80% of the channel height. In yet more embodiments, the one or more p-doped regions exhibits a doping concentration of greater than or about 5×10¹⁶ cm⁻³ to about 1×10²⁰ cm⁻³. Moreover, in embodiments, the channel exhibits a height extending between the source/drain region and a second source/drain region, wherein the one or more p-doped regions has a thickness that is from about 5% to about 30% of the channel height.

The present technology is also generally directed to vertical cell array transistors (VCATs). Transistors include a plurality of bit lines arranged in a first horizontal direction, a plurality of word lines arranged in a second horizontal direction, and a plurality of channels extending from a first source/drain region to a second source/drain region in a vertical direction. Transistors include where the vertical direction is generally orthogonal to the first horizontal direction and the second horizontal direction such that the plurality of bit lines intersect with the first source/drain region and/or second source/drain region of the plurality of channels, and the plurality of word lines intersect with a gate region of the plurality of channels. Transistors include where at least a portion of the plurality of channels include one or more p-doped regions disposed between the first source/drain region and the second source/drain region.

In embodiments, the at least a portion of the plurality of channels exhibit a height extending between the first source/drain region and the second source/drain region, where the one or more p-doped regions is formed at a height of about 20% to about 80% of the channel height. In more embodiments, transistors further include at least a second p-doped region of the one or more p-doped regions. Furthermore, in embodiments, the one or more p-doped regions exhibits a doping concentration of greater than or about 5×10¹⁶ cm⁻³ to about 1×10²⁰ cm⁻³. In yet more embodiments, the channel exhibits a height extending between the first source/drain region and the second source/drain region, where the one or more p-doped regions has a thickness that is from about 5% to about 30% of the channel height.

The present technology is also generally directed to methods of forming a vertical cell array transistor (VCAT). Methods include etching a substrate to form one or more shallow trench isolations and a plurality of vertically extending channels. Methods include contacting one or more of the plurality of vertically extending channels with one or more ion implants, forming a first source/drain region. Methods include forming a p-doped region along one or more of the plurality of vertically extending channels and forming a second source/drain region. Methods include where the first source/drain region contains a first section adjacent to a source/drain junction and a second section adjacent to a channel body, where the first section has a doping concentration that greater than a doping concentration of the second section.

In embodiments, the p-doped region is formed utilizing a second ion implant. In more embodiments, methods include annealing the one or more ion implants and/or the second ion implant. In further embodiments, methods include etching a portion of the one or more of the plurality of channels, and forming the p-doped region within the etched portion. Moreover, in embodiments the forming comprises epitaxially growing the p-doped region.

Such technology may provide numerous benefits over conventional systems and techniques. For example, the processes and systems may reduce the floating body effect, as well as reduce threshold voltage degradation over time. Additionally, the processes and systems may significantly improve gate-induced drain leakage, such as by providing a gradual change in a potential of the storage node contact at one or more source/drain regions as compared to a channel potential. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 2 shows selected operations in a formation method according to embodiments of the present technology.

FIG. 3A shows a perspective view of a semiconductor structure according to embodiments of the present technology with a dielectric material fill after shallow trench isolation formation.

FIG. 3B shows a perspective view of a semiconductor structure according to embodiments of the present technology patterned for second shallow trench isolation formation.

FIG. 3C shows a perspective view of a semiconductor structure according to embodiments of the present technology with a gate oxide and low work function material deposited word line isolations.

FIG. 3D shows a perspective view of a semiconductor structure according to embodiments of the present technology with doped source/drain regions.

FIG. 4A shows cross sectional illustration of a junction according to embodiments of the present technology.

FIG. 4B shows cross sectional illustration of a junction according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Historically, DRAM chip bit densities have been increasing by approximately 25% node over node. However, the node over node increase in bit density has trended down to closer to 20% for the more recent generations, mainly due to the challenges with scaling the cell area. Cell design architecture for modern DRAM technology has been based on 6F² geometry, where “F” is the minimum feature size for a given technology node. Switching from 6F² to 4F² cell architecture could result in a 33% increase in bit density at the same technology node. In addition, patterning difficulties for 4F² DRAM are greatly reduced as compared to 6F². This is due at least in part to the fact that in the 4F² DRAM scheme, the capacitor and bit line are located at two ends of a vertical cell transistor, instead of tightly packed on the same side as in 6F² DRAM.

However, the 4F² DRAM design comes with its own challenges. For example, 4F² memory cells have the transistor channel disposed between the bitline and the capacitor layers, leaving no common substrate connecting the channels, resulting in a floating body effect for these transistors. For instance, it is believed that conventional 4F² DRAM access devices exhibit off-leakage current issues. Off-leakage current results from the floating body effect, such as hole accumulation in the body of a 4F² DRAM device due to the isolated channels. Electron-hole pairs can form in a semiconductor channels due to band-to-band tunneling. While the electrons can flow into the n-type source or drain regions of the transistor, the holes cannot. For 4F² DRAM devices without a substrate connection, the holes have no path to leave the channel and will continue to accumulate. Thus, the floating body effect may lead to channel activation without gate activation, which eventually translates into leakage current from the capacitor, or data storage side of the device, as well as into degradation of the threshold voltage over time. Attempts have been made to provide body connections utilizing a buried body contact scheme. However, such attempts can result in gate overlap to a source/drain junction edge, allowing undesired gate-induced drain leakage, or limited scalability to small dimensions. Moreover, such design schemes are also capable of producing high aspect ratio structures that challenge existing doping techniques.

Due at least in part to the floating body effect, vertical channel access array transistors (VCAATs) are more susceptible to elevated leakage current values, such as gate induced drain leakage. This phenomena may further exacerbate the floating body effect. For instance, as holes continue to accumulate, charge may accumulate on the bit line, reducing the potential between the channel and the storage node. This may allow increased band-to-band tunneling, and further decrease the threshold voltage of the access transistor.

The present technology overcomes these and other problems by providing a source/drain doping profile that reduces the rate of change of the storage node contact potential at one or more source/drain regions. Namely, by carefully controlling the doping profile of one or more source/drain regions, a barrier between a channel potential and a storage node contact potential may be increased. As band-to-band tunneling is exponentially related to barrier thickness, systems and devices discussed herein may exhibit a drastically reduced band-to-band tunneling, and therefore floating body effect. Moreover, the present technology has found that by carefully forming one or more sinks within a channel region, holes may be further dissipated, further improving the floating body effect. Thus, unlike prior attempts, the present technology may provide a word line that maintains a necessary threshold voltage for low off current leakage while reducing the gate induced drain leakage, and even the floating body effect of a vertical channel access array transistor (VCAAT).

Although the remaining disclosure will routinely identify specific deposition and etch processes utilized for forming vertical cell access array transistors (VCAATs), such as a 4F² DRAM device, it will be readily understood that the systems and methods are equally applicable to other DRAM devices, including gate-all-around and Schottky barrier VCAATs, other devices suffering from a floating body effect, and orientations thereof, as well as processes for forming such devices. Accordingly, the technology should not be considered to be so limited as for use with these specific devices or systems alone. The disclosure will discuss one possible semiconductor device that may include one or more components, utilizing one or more word lines according to embodiments of the present technology before additional variations and adjustments to this apparatus according to embodiments of the present technology are described.

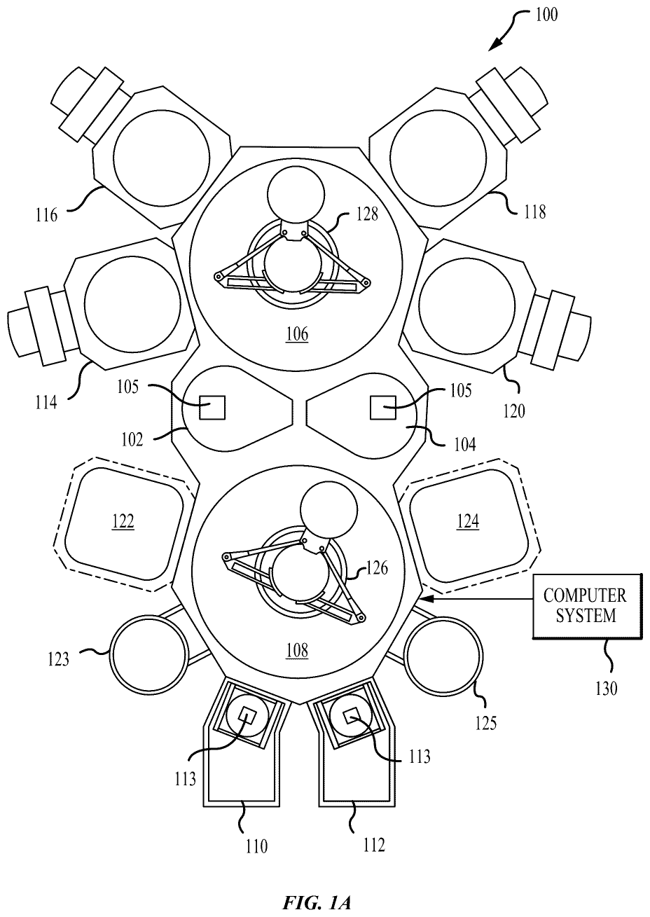

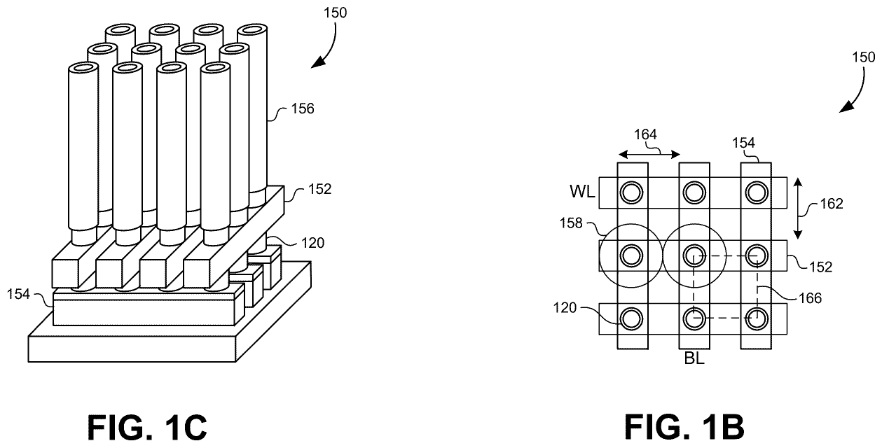

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B and 1C illustrate top and perspective views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

A plurality of vertical memory cells may be arranged over intersections between the plurality of word lines 152 and the plurality of bit lines 154. Each of the plurality of vertical memory cells may include a vertical transistor, which may be referred to as a vertical pillar transistor or vertical column transistor. A channel material for the transistor may be formed from a single-crystal silicon pillar, or any other substrates discussed in greater detail below. This silicon channel may be formed by etching the substrate. Each of the plurality of vertical memory cells may also include a vertical capacitor 156. The vertical memory cell may operate by storing a charge on the vertical capacitors 156 to indicate a saved memory state. However, while FIGS. 1B and 1C illustrate the arrangement of the vertical transistors and capacitors in a rectangular generally orthogonal grid pattern (where “generally orthogonal” may be within about 10° from orthogonal, such as less than or about 7.5°, such as less than or about 5°, such as less than or about 2.5°, such as less than or about 1° from orthogonal, or any ranges or values therebetween, where “generally” may be utilized to similarly vary “vertical”, “horizontal” and the like), it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166 for this conventional 4F² memory array for comparison to the simple memory array described below. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166.

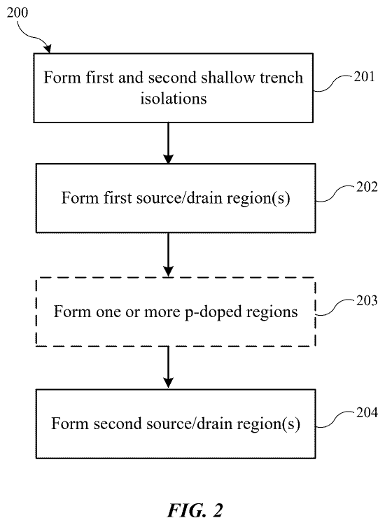

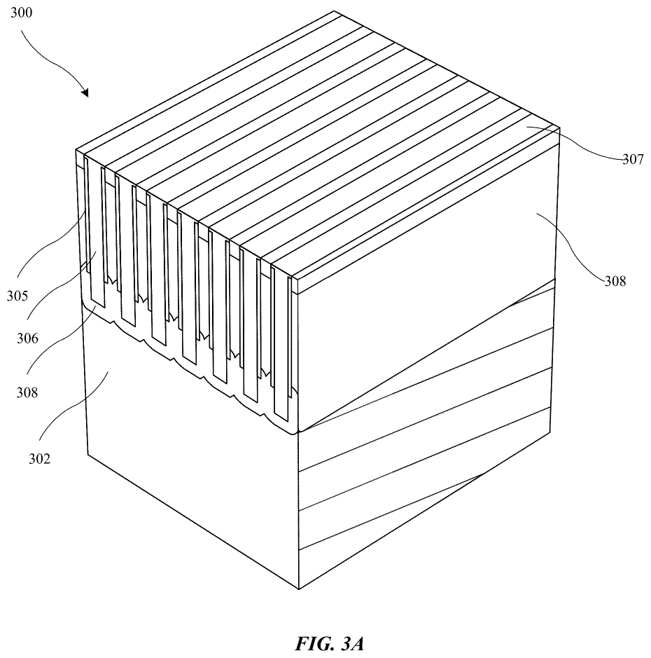

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically, it should be understood that the other orientation from bit line to word line side may be utilized.

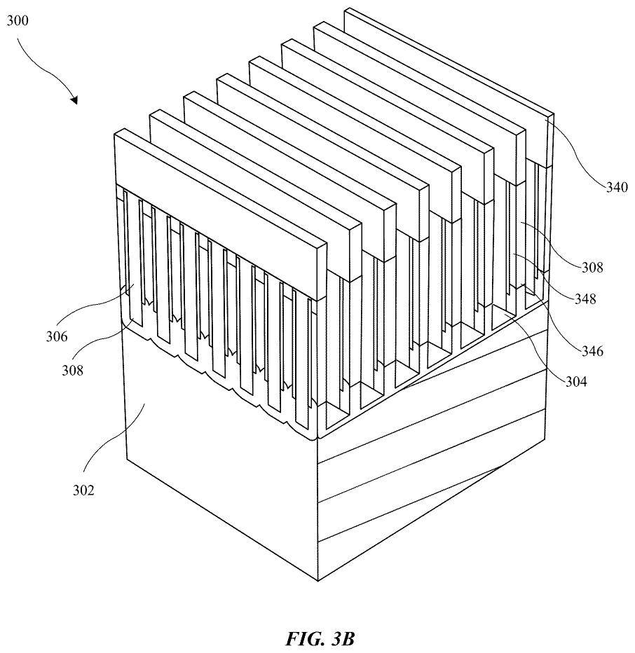

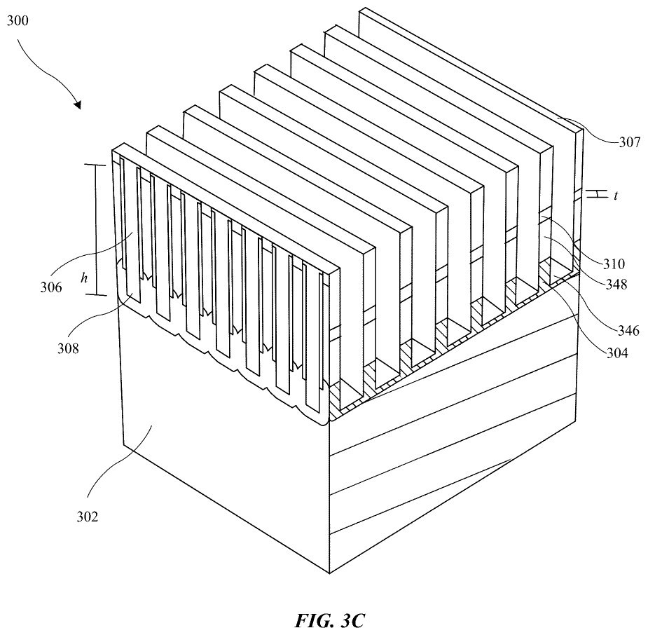

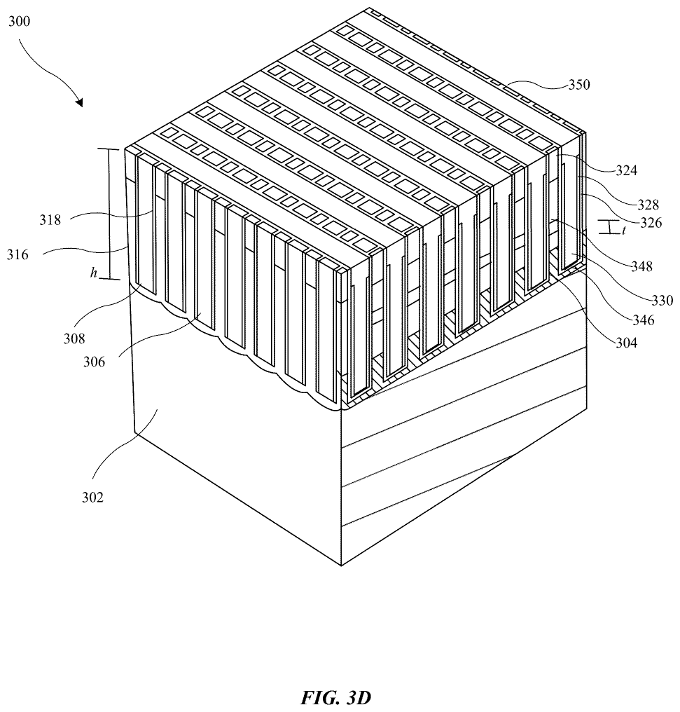

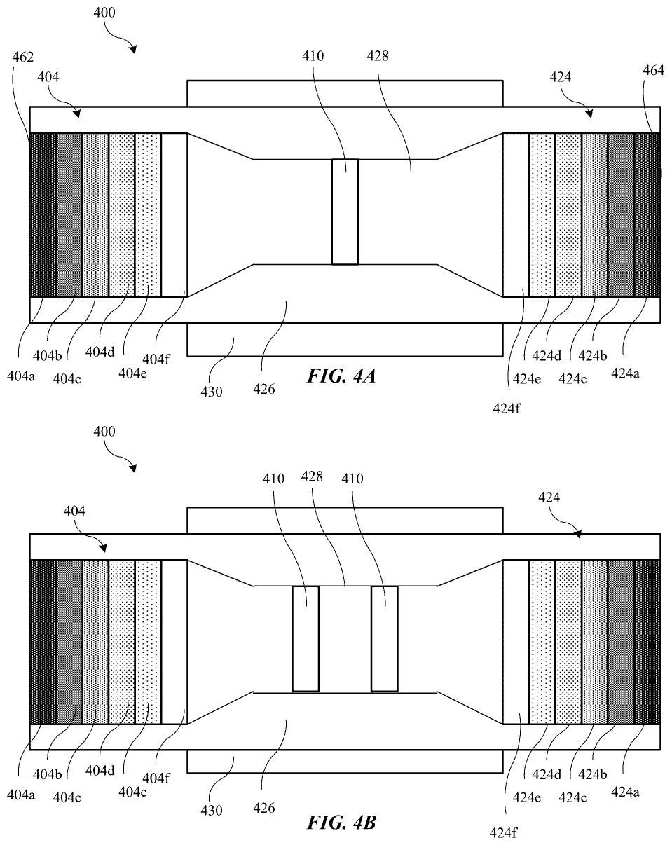

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations shown schematically in FIGS. 3A-3D, 4A, and 4B, the illustrations of which will be described in conjunction with the operations of method 200. It is to be understood that FIGS. 3A-3D, 4A, and 4B illustrate only partial schematic views, and a semiconductor substrate may include further components as illustrated in the figures, as well as alternative components, of any size or configuration that may still benefit from aspects of the present technology.

Method 200 may or may not involve optional operations to develop the semiconductor structure to a particular fabrication operation. It is to be understood that method 200 may be performed on any number of semiconductor structures 300 or substrates 302, as illustrated in FIGS. 3A-3D, 4A, and 4B, including exemplary structures on which a selective deposition material may be formed. As illustrated in FIG. 3A substrate 302 may be any number of materials, such as a base wafer or substrate made of silicon or silicon-containing materials, germanium, other substrate materials, as well as one or more materials that may be formed overlying the substrate during semiconductor processing.

In embodiments, the structure 300 may be a semiconductor substrate, including bulk substrates, epitaxially grown substrates, and/or silicon on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 302 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

As illustrated in FIG. 3A, structure 300 is provided that includes a substrate 302 that has already undergone shallow trench isolation formation 308, and first dielectric material 306 fill in shallow trench isolations 308. In addition, two or more walls 305 are formed between respective first shallow trench isolations 308, where the illustrated walls 305 are spaced apart in a horizontally extending row generally perpendicular to a word line direction in this embodiment. However, as would be understood by one having skill in the art, in embodiments, shallow trench isolations may be first cut in a direction generally parallel to the word line direction.

While various deposition and fill processes will be described, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

Nonetheless, at operation 201, method 200 may include forming both first shallow trench isolations as illustrated in FIG. 3A and second shallow trench isolations 346 as illustrated in FIG. 3B. For instance, in embodiments, a substrate 302 may be loaded into load lock 110,112, and transferred to a process chamber (such as process chamber 114) via robots 126, 128, where the semiconductor structure 300 may undergo mask 340 formation and second shallow trench isolation 346 formation, which may also be referred to as word line trench formation herein as the second shallow trench isolations 346 may extend in a generally horizontal direction that is generally parallel to the word line direction, at operation 201. For instance, FIG. 3B illustrates forming mask 340, which may be any patterning mask as known in the art, and etching of walls 305 into channels 348 by etching in a direction extending in a second horizontal direction that is generally perpendicular to the first horizontal direction in embodiments, utilizing mask 340. Namely, as discussed above for the formation of shallow trench isolations 308 between walls 305, a pattern or mask 340 defining second shallow trench isolations 346 may be used to form the isolations between channels 348, which run in a row parallel or in plane with word lines, in this embodiment, formed by an etch process. The resulting channels 348 may have a uniform or nonuniform width, and/or a width generally equal to walls 305. The second shallow trench isolations 346 may serve to isolate neighboring channels 348. Thus, as illustrated in FIGS. 3A and 3B, a semiconductor structure 300 may be provided that includes first and second shallow trench isolations, where the first shallow trench isolation may contain a deposited or filled dielectric material as discussed above. It should be understood that the substrate may be transferred between each operation step, or only a portion of the operation steps, as some operation steps may be completed in the same processing chamber.

As illustrated in FIG. 3C, in embodiments, source/drain regions 304 formation is conducted as and may include one or more ion implants followed by a subsequent anneal process. The implant process may be a single implant or may include a series of multiple implants, as will be discussed in greater detail below. When multiple implants are utilized, each implant may utilize the same ion, or different ions. Although, it should be understood that the source/drain region 304 may be formed from any suitable process, in embodiments, source/drain region 304 may be imparted with one or more doping gradients. Namely, as will be discussed in greater detail in regards to FIGS. 4A and 4B, the present technology has surprisingly found that by utilizing a doping gradient for the first source/drain regions 304 and/or second source/drain region 324, a rate of change of the storage note contact potential at the respective source/drain region may be carefully tailored, reducing the risk of band-to-band tunneling and the floating body effect. Nonetheless, the method may include providing a semiconductor structure having first source/drain regions 304 for a plurality of vertical channels, and forming a plurality of word lines that contact the first source/drain regions. However, in embodiments, first source/drain region 304 formation may occur prior to operation 201. Overall, this process may incrementally form each stage of the transistor on top of a previous completed stage.

Optional operation 203 may include forming one or more p-doped region in one or more channels 348. While the uniquely formed source/drain regions 304/324 according to the present technology may address the floating body effect and other problems discussed above, in embodiments, it may be desirable to further include one or more p-doped regions 310. Namely, the present technology has surprisingly found that by including one or more p-doped regions 310 within one or more channels 348, the p-doped regions may act as a sink for hole accumulation. Moreover, such p-doped regions 310 may also increase the threshold voltage of the channel, broadening the voltage range at which the channel is in an off orientation, and reducing gate induced drain leakage.

In embodiments, the one or more doped regions 310 may have a sufficient doping level to prevent significant charge sharing, e.g., a level of doping sufficient to provide a Vₜ above a gate threshold for the respective channel 348 where the p-doped region 310 is formed. Nonetheless, as each p-doped region 310 has a higher level of dopant than the channel 348, each p-doped region 310 may diffuse dopant from the center of the respective p-doped region 310, towards and into the adjacent channels 348. The diffusion may therefore form a gradient of dopant from each p-doped region 310 towards source/drain regions 304,324. Such a phenomena may improve hole attraction, reducing the floating body effect, as holes may move from problematic areas of one or more channels 348 into p-doped region 310, collecting the holes and dissipating the effects. However, if the doping level is too high in the one or more p-doped region 310 compared to the respective channel 348, diffusion of dopant may increase the doping level of the one or more channels 348 to a level above a threshold value for the channel 348. Therefore, in embodiments, the doping level of each p-doped region 310 compared to the channel 348 is carefully selected. Regardless, the present technology has surprisingly found that p-doped region 310 drastically reduce the floating body effect, such as by reducing channel potential increases and reducing off-leakage current.

In embodiments, the doping concentration of the one or more p-doped regions 310 may be greater than or about 5×10¹⁶ cm⁻³, such as greater than or about 6×10¹⁶ cm⁻³, such as greater than or about 7×10¹⁶ cm⁻³, such as greater than or about 8×10¹⁶ cm⁻³, such as greater than or about 9×10¹⁶ cm⁻³, such as greater than or about 1×10¹⁷ cm⁻³, such as greater than or about 2×10¹⁷ cm⁻³, such as greater than or about 4×10¹⁷ cm⁻³, such as greater than or about 6×10¹⁷ cm⁻³, such as greater than or about 8×10¹⁷ cm⁻³, such as greater than or about 1×10¹⁸ cm⁻³, such as greater than or about 2×10¹⁸ cm⁻³, such as greater than or about 4×10¹⁸ cm⁻³, such as greater than or about 6×10¹⁸ cm⁻³, such as greater than or about 8×10¹⁸ cm⁻³, such as greater than or about 1×10¹⁹ cm⁻³, such as greater than or about 2×10¹⁹ cm⁻³, or such as less than or about 1×10²⁰ cm⁻³, such as less than or about 8×10¹⁹ cm⁻³, such as less than or about 6×10¹⁹ cm⁻³, such as less than or about 4×10¹⁹ cm⁻³, such as less than or about 2×10¹⁹ cm⁻³, or any ranges or values therebetween.

Nonetheless, in embodiments, a number of different materials may be used for the one or more p-doped region 310. For example, the one or more p-doped region 310 may include a crystalline semiconductor, such as silicon, germanium, silicon germanium, one or more dielectric materials, and/or other suitable structural support materials. In embodiments, the one or more p-doped regions may be formed from a crystalline silicon, such as a single crystalline silicon in embodiments, or any one or more of the semiconductor materials discussed above, dielectric materials, as well as any other materials that are suitable for deposition between adjacent channels to provide structural support. Nonetheless, these materials may also be used in a polycrystalline semiconductor form.

In embodiments, the one or more p-doped region 310 may be formed by epitaxially growing a material on a recessed channel material 348 in shallow trench isolation 308. Thus, in embodiments, such a processes may be referred to as a selective epi-deposition process. Alternatively, the one or more p-doped region 310 may be formed by conformally filling between adjacent shallow trench isolations 308 with one or more p-doped region 310 materials, or by depositing one or more p-doped region 310 materials utilizing other deposition methods known in the art. Additionally or alternatively, a portion of channel 348 may be doped, such as by an implant and anneal process. Regardless of the method used, it should be clear that the material used for the one or more p-doped region 310 is deposited, grown, or formed. If a deposition or growth method is utilized, a second channel material, which may be the same channel materials discussed above, may be formed over p-doped region 310, forming channel 348.

In embodiments, the one or more p-doped region 310 are only formed in a portion of one or more channels 348. For instance, as illustrated in FIG. 3C, the one or more p-doped region 310 have a thickness t that is from about 5% to about 30% of a height h of the respective channel 348, such as greater than or about 7.5%, such as greater than or about 10%, such as greater than or about 12.5%, such as greater than or about 15%, such as greater than or about 17.5%, such as greater than or about 20%, such as greater than or about 22.5%, such as greater than or about 25%, such as greater than or about 27.5%, or such as less than or about 30%, such as less than or about 27.5%, such as less than or about 25%, such as less than or about 22.5%, such as less than or about 20%, or any ranges or values therebetween. By selecting one or more p-doped regions 310 each having a thickness or where a total p-doped region thickness is according to the above ranges, excellent floating body effect and leakage current properties may be exhibited without negatively effecting the channel.

Stated differently, in embodiments, the thickness t of the one or more p-doped regions 310 may be greater than or about 2 nm, such as greater than or about 4 nm, such as greater than or about 6 nm, such as greater than or about 8 nm, such as greater than or about 10 nm, such as greater than or about 12 nm, such as greater than or about 14 nm, such as greater than or about 16 nm, such as greater than or about 18 nm, such as greater than or about 20 nm, such as greater than or about 22 nm, such as greater than or about 24 nm, such as greater than or about 26 nm, such as greater than or about 28 nm, such as greater than or about 30 nm, such as greater than or about 32 nm, such as greater than or about 34 nm, such as greater than or about 36 nm, such as greater than or about 38 nm, such as greater than or about 40 nm, or such as less than or about 70 nm, such as less than or about 60 nm, such as less than or about 50 nm, such as less than or about 55 nm, such as less than or about 50 nm, such as less than or about 45 nm, such as less than or about 40 nm, or any ranges or values therebetween. Namely, in embodiments, the thickness may be selected so as to provide sufficient sink and doping properties without impacting the overall electrical properties of the respective channel.

In addition, as discussed above, in embodiments, the one or more p-doped regions 310 may be formed at approximately a center point of the respective channel 348 between first and second source/drain regions, or such as between source/drain 304 and top surface 307 in FIG. 3C. Namely, by utilizing one or more p-doped regions 310 at an approximate center point, greater hole distribution may be exhibited as well as reduced gate induced drain leakage. However, it should be understood that in embodiments, more than one p-doped region 310 may be utilized within a respective channel, and neither or one of such p-doped regions 310 may not be located at approximately a center point. For instance, as a p-doped regions 310 may be disposed adjacent to a source/drain region 304 and a p-doped regions 310 may be formed adjacent to a second source drain region of semiconductor structure 300 (see, e.g., FIG. 4B). Nonetheless, regardless of the number of p-doped regions 310 utilized within each respective channels, the channel 348 may have a height h extending between first and second source/drain regions, and at least one of the p-doped regions may be formed at a height of about 20% to about 80% of the channel height, such as from about 30% to about 70%, such as from about 40% to about 60%, such as from about 45% to about 55%, or any ranges or values therebetween.

After formation of the one or more p-regions 310 and optionally the upper portion of channel 348, if necessary, the structure 300 may re-enter a normal process flow for a vertical cell DRAM array, such as a 4F² DRAM array, and undergo one or more further processing steps, until doping of second source/drain regions 324 at operation 204. For instance, as illustrated, gate dielectric 326 and a gate metal 328 may be formed along shallow trench isolations 346. Furthermore, a second dielectric 330 may be filled into shallow trench isolations 346 after formation of the gate dielectric 326 and gate metal 328.

In embodiments, the gate metal 328 may be a material such as a low-resistance metal, including as tungsten, titanium nitride, titanium, ruthenium, cobalt, molybdenum, the like, or combinations thereof. In embodiments, the gate dielectric 326 may be formed from any dielectric material as known in the art, such as a silicon nitride, a silicon oxynitride, silicon dioxide, silicon oxide or other similar materials. In addition, second dielectric material 330 may be formed from any one or more of the dielectric materials discussed herein. Nonetheless, as illustrated, second source/drain regions 324 may be formed by any one or more of the methods discussed above, or as will be discussed in greater detail below. In embodiments, second source/drain regions 324 may be formed prior to filling of second dielectric material 330. Additionally or alternatively, second dielectric material 330 may be filled, and etched back to a depth below the desired source/drain region 324 of channel 348. After the etch back, an implant, implants, or other method may be utilized to form second source/drain regions 324, followed by refilling of second dielectric material 330.

Nonetheless, in embodiments, one or more of the first source/drain regions 404 and/or second source/drain regions 424 may be formed to exhibit a doping gradient as illustrated in FIGS. 4A and 4B. In embodiments, the first source/drain region 404, second source/drain region 424, or both the first source/drain region 404 and second source/drain region 424 may have a first section 404a/424a adjacent to an end surface such as bitline 462 and storage node contact 464 of the channel 448. The first section 404a/424a exhibits a higher doping concentration than the other sections, such as all of the other sections, of source/drain region 404/424. In embodiments, the first section of the respective source/drain region may be directly adjacent to the end surface such as bitline 462 and storage node contact 464 of the respective channel, and may form all or portion of the end surface (e.g. may form a source/drain junction). Reference character 426 of FIGS. 4A and 4B denotes the gate oxide of the transistor that might be single layer or multi-layer formed of single or multiple dielectric layers. The one or more gate oxide layers can include SiO2, SiON, SiN, HfO2, HfZrO, different doping of HfOx, other oxides as known in the art, and combinations thereof. While FIGS. 4A and 4B are shown in cross-section, in embodiments, gate oxide 426 may extend around channel 448, for example, in a gate-all-around structure.

Furthermore, opposed end regions, illustrated by section 404f/424f in FIGS. 4A and 4B, may be disposed adjacent to the gate 430 of the transistor which doubles as a wordline 430, and may form an interface with the wordline 430. In embodiments, the sections adjacent to the channel body may have a lower doping concentration than the other sections, such as all of the other sections, of source/drain region 404/424. While FIGS. 4A and 4B are shown in cross-section, it should be understood that in embodiments, wordline 430 may extend around channel 448, for example, in a gate-all-around structure.

For instance, in embodiments, all or a portion of first section 404a and/or 424a may have a doping concentration of greater than or about 5×10¹⁹ cm⁻³, such as greater than or about 6×10¹⁹ cm⁻³, such as greater than or about 7×10¹⁹ cm⁻³, such as greater than or about 8×10¹⁹ cm⁻³, such as greater than or about 9×10¹⁹ cm⁻³, such as greater than or about 1×10²⁰ cm⁻³, such as greater than or about 2×10²⁰ cm⁻³, such as greater than or about 3×10²⁰ cm⁻³, such as greater than or about 4×10²⁰ cm⁻³, such as greater than or about 5×10²⁰ cm⁻³, such as greater than or about 6×10²⁰ cm⁻³, such as greater than or about 7×10²⁰ cm⁻³, such as greater than or about 8×10²⁰ cm⁻³, such as greater than or about 9×10²⁰ cm⁻³, or such as less than or about 1×10²¹ cm⁻³, such as less than or about 9×10²⁰ cm⁻³, such as less than or about 8×10²⁰ cm⁻³, such as less than or about 7×10²⁰ cm⁻³, such as less than or about 6×10²⁰ cm⁻³, or any ranges or values therebetween. In embodiments, end surface 462 and/or 464 may exhibit any one or more of the above concentrations, and the concentration may decrease moving away from end surface 462/464 towards channel body 428.

Furthermore, in embodiments, all or a portion of section 404f and/or 424f may have a doping concentration of less than or about 5×10¹⁹ cm⁻³, such as less than or about 4×10¹⁹ cm⁻³, such as less than or about 3×10¹⁹ cm⁻³, such as less than or about 2×10¹⁹ cm⁻³, such as less than or about 1×10¹⁹ cm⁻³, such as less than or about 9×10¹⁸ cm⁻³, such as less than or about 8×10¹⁸ cm⁻³, such as less than or about 7×10¹⁸ cm⁻³, such as less than or about 6×10¹⁸ cm⁻³, such as less than or about 5×10¹⁸ cm⁻³, such as less than or about 4×10¹⁸ cm⁻³, such as less than or about 3×10¹⁸ cm⁻³, such as less than or about 2×10¹⁸ cm⁻³, such as less than or about 1×10¹⁸ cm⁻³, or such as greater than or about 5×10¹⁷ cm⁻³, or such as greater than or about 6×10¹⁷ cm⁻³, or such as greater than or about 7×10¹⁷ cm⁻³, or such as greater than or about 8×10¹⁷ cm⁻³, or such as greater than or about 9×10¹⁷ cm⁻³, or such as greater than or about 1×10¹⁸ cm⁻³, or any ranges or values therebetween.

Thus, in embodiment, first section 404a and/or 424a may have a doping concentration that is higher than a doping concentration of section 404f and/or 424f. In embodiments, first section 404a and/or 424a adjacent to one or more ends 462/464 may have a doping concentration that is at greater than or about 1.5 times higher than a doping concentration of section 404f and/or 424f adjacent to channel body 428, such as greater than or about 2 times, such as greater than or about 2.5 times, such as greater than or about 3 times, such as greater than or about 3.5 times, such as greater than or about 4 times, such as greater than or about 4.5 times, such as greater than or about 5 times, such as greater than or about 5.5 times, such as greater than or about 6 times, such as greater than or about 6.5 times, such as greater than or about 7 times, such as greater than or about 7.5 times, such as greater than or about 8 times, such as greater than or about 8.5 times, such as greater than or about 9 times, such as greater than or about 9.5 times, such as even greater than or about 10 times higher than a doping concentration of a section adjacent to or forming a contact with channel body 428, or gate/wordline 430.

Surprisingly, the present technology has found that by utilizing a generally Gaussian or normal distribution in relation to doping concentration extending from end surface 462 and/or 464 to the section 404f and/or 424f adjacent to the channel body 428 in case of double gate VCAAT embodiment and wordline in case of gate-all-around embodiment VCAAT (e.g. where a peak concentration is disposed at, or generally at, end surface 462 and/or 464), the storage node contact potential may be controlled to greatly reduce, if not eliminate, the occurrence of band-to-band tunneling, the floating body effect, and/or gate induced leakage current. Namely without wishing to be bound by theory, it is believed that by forming one or more source drain regions according to the gradients discussed herein, the change in potential may have a smaller slope, increasing a barrier thickness between the storage node contact potential and the channel potential. This decreases the risk of band-to-band tunneling due to the increased barrier thickness, and also provides for increased hole accumulation prior to band-to-band tunneling occurring due to increases in the channel potential. The present technology may also, therefore, decrease threshold voltage degradation over time.

While there are four additional sections illustrated in source/drain regions 404/424 (404b-404c, 424b-424c), it should be clear that the source/drain region 404 and/or 424 may have any number of sections so as one or more source/drain regions 404/424 exhibit the gradient discussed above. Furthermore, in embodiments, there may be no delineated sections, as instead, the doping concentration may gradually decrease moving from end 462/464 towards channel body 428 or increase moving from region 404f/424f adjacent to channel body 428 in case of double gate VCAAT embodiment and wordline in case of gate-all-around embodiment VCAAT, towards channel end 462/464 according to the distribution discussed above.

In embodiments, the source/drain regions 404/424 may be formed by any one or more methods as known in the art so long as the gradient is provided. In embodiments, multiple implants may be utilized. For instance, the source/drain region may first be contacted with a lightly doped implant adjacent to a channel body, followed by one or more higher energy implants moving outward towards an end surface 462/464. Alternatively, a single or multiple implants may be utilized, but various anneal temperatures may be utilized. Furthermore, in embodiments, a combination of methods may be utilized, such as forming one or more lightly doped regions, followed by a high energy implant and/or varied anneal temperatures. Nonetheless, it should be clear that various methods may be utilized to form source/drain regions 404/424 so long as a proper gradient is imparted.

Regardless of how or when the source/drain regions 304 and 324 are formed, the semiconductor structure 300/400 may re-enter a normal process flow, and undergo one or more further processing steps. For instance, the semiconductor structure may undergo contact redistribution, bonding pad formation, and/or copper contact formation. Nonetheless, semiconductor structure may exhibit a drastically reduced gate induced leakage current, off current leakage, and/or floating body effect.

It should be appreciated that the specific steps illustrated in the figures provide particular methods of forming 4F² DRAM arrays according to various embodiments. Other sequences of steps may also be performed according to alternative embodiments. For example, alternative embodiments may perform the steps outlined above in a different order. Moreover, the individual steps illustrated in the figures may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A vertical cell access array transistor (VCAAT), comprising:
one or more bit lines arranged in a first horizontal direction;
one or more word lines arranged in a second horizontal direction;
one or more channels extending in a vertical direction that is generally orthogonal to the first horizontal direction and the second horizontal direction such that the one or more bit lines intersect with a source/drain region of the one or more channels, and the one or more word lines intersect with a gate region of the one or more channels;
wherein the source/drain region comprises a first section adjacent to a source/drain junction and a second section adjacent to a channel body, wherein the first section has a doping concentration that greater than a doping concentration of the second section.

2. The vertical cell array transistor (VCAAT) of claim 1, wherein a doping concentration of the source/drain region exhibits a Gaussian (normal) distribution having a peak concentration at approximately the source/drain junction.

3. The vertical cell array transistor (VCAAT) of claim 1, wherein the doping concentration of the first section is greater than or about 2 times higher than the doping concentration of the second section.

4. The vertical cell array transistor (VCAAT) of claim 1, wherein the doping concentration of the first section is greater than 1×10¹⁹ cm⁻³.

5. The vertical cell array transistor (VCAAT) of claim 4, wherein the doping concentration of the first section is greater than 4×10¹⁹ cm⁻³.

6. The vertical cell array transistor (VCAAT) of claim 1, wherein the doping concentration of the second section is less than or about 1×10¹⁹ cm⁻³.

7. The vertical cell array transistor (VCAAT) of claim 1, wherein the channel further comprises one or more p-doped regions.

8. The vertical cell array transistor (VCAAT) of claim 7, wherein the channel comprises a height extending between the source/drain region and a second source/drain region, wherein the one or more p-doped regions is formed at a height of about 20% to about 80% of the channel height.

9. The vertical cell array transistor (VCAAT) of claim 7, wherein the one or more p-doped regions comprises a doping concentration of greater than or about 5×10¹⁶ cm⁻³ to about 1×10²⁰ cm⁻³.

10. The vertical cell array transistor (VCAAT) of claim 7, wherein the channel comprises a height extending between the source/drain region and a second source/drain region, wherein the one or more p-doped regions comprise a thickness that is from about 5% to about 30% of the channel height.

11. A vertical cell array transistor (VCAAT), comprising:
a plurality of bit lines arranged in a first horizontal direction;
a plurality of word lines arranged in a second horizontal direction;
a plurality of channels extending from a first source/drain region to a second source/drain region in a vertical direction that is generally orthogonal to the first horizontal direction and the second horizontal direction such that the plurality of bit lines intersect with the first source/drain region and/or second source/drain region of the plurality of channels, and the plurality of word lines intersect with a gate region of the plurality of channels;
wherein at least a portion of the plurality of channels comprise one or more p-doped regions disposed between the first source/drain region and the second source/drain region.

12. The vertical cell array transistor (VCAAT) according to claim 11, wherein the channel comprises a height extending between the first source/drain region and the second source/drain region, wherein the one or more p-doped regions is formed at a height of about 20% to about 80% of the channel height.

13. The vertical cell array transistor (VCAAT) according to claim 11, further comprising at least a second p-doped region of the one or more p-doped regions.

14. The vertical cell array transistor (VCAAT) according to claim 13, wherein the one or more p-doped regions comprises a doping concentration of greater than or about 5×10¹⁶ cm⁻³ to about 1×10²⁰ cm⁻³.

15. The vertical cell array transistor (VCAAT) according to claim 11, wherein the channel comprises a height extending between the first source/drain region and the second source/drain region, wherein the one or more p-doped regions comprise a thickness that is from about 5% to about 30% of the channel height.

16. A method of forming a vertical cell array transistor (VCAAT), comprising:
etching a substrate to form one or more shallow trench isolations and a plurality of vertically extending channels;
contacting one or more of the plurality of vertically extending channels with one or more ion implants, forming a first source/drain region;
forming a p-doped region along one or more of the plurality of vertically extending channels; and
forming a second source/drain region;
wherein the first source/drain region comprises a first section adjacent to a source/drain junction and a second section adjacent to a channel body, wherein the first section has a doping concentration that greater than a doping concentration of the second section.

17. The method of claim 16, wherein the p-doped region is formed utilizing a second ion implant.

18. The method of claim 17, comprising annealing the one or more ion implants and/or the second ion implant.

19. The method of claim 16, comprising etching a portion of the one or more 2 of the plurality of channels, and forming the p-doped region within the etched portion.

20. The method of claim 19, wherein the forming comprises epitaxially growing the p-doped region.
